(19) United States
(12) Patent Application Publication
(10) Pub. No.: US 2011/0163181 A1
(43) Pub. Date: Jul. 7, 2011

(54) FILM FORMATION METHOD, FILM FORMATION DEVICE, PIEZOELECTRIC FILM, PIEZOELECTRIC DEVICE AND LIQUID DISCHARGE DEVICE

(76) Inventors: Takamichi Fujii, Kanagawa-ken (JP); Takayuki Naono, Kanagawa-ken (JP); Takaml Arakawa, Kanagawa-ken (JP)

(21) Appl. No.: 13/119,842

(22) PCT Filed: Sep. 16, 2009
(86) PCT No.: PCT/JP2009/004658

§ 371 Date: Mar. 18, 2011

(30) Foreign Application Priority Data
Sep. 19, 2008 (JP) 2008-241244

(51) Int. Cl. B05B 1/08; H01L 41/18; H05H 1/24; C23C 16/50; C23C 14/34; H01L 41/08; H01L 41/22

(52) U.S. Cl. 239/102.2; 252/62.9 R; 427/569; 204/192.12; 118/723 R; 310/311

(57) ABSTRACT

When a film containing constituent elements of a target is formed on a substrate through a vapor deposition technique using plasma with placing the substrate and the target to face each other, film formation is carried out with controlling variation of plasma potential Vs (V) in a plasma space in an in-plane direction of the substrate to be within ±10V at a distance of 2-3 cm from a surface of the target toward the substrate.

### TECHNICAL FIELD

The present invention relates to a film formation method and a film formation device for forming, on a substrate, a film containing constituent elements of a target through vapor deposition using plasma. The present invention also relates to a piezoelectric film formed with the film formation method, as well as a piezoelectric device and a liquid discharge device including the piezoelectric film.

### BACKGROUND ART

Sputtering is a film formation method, in which a substrate and a target are placed to face each other, and a gas which is plasmized under reduced pressure is made to collide against the target, so that the energy of the collision makes molecules or atoms be ejected from the target and deposited on the substrate. Japanese Unexamined Patent Publication Nos. 11 (1999)-335828 and 11 (1999)-350126 (hereinafter referred to as patent documents 1 and 2, respectively) each discloses a film formation device which is intended to achieve a homogenous film thickness distribution in the in-plane direction in a typical film formation process using sputtering.

Patent document 1 discloses a sputter film formation device, which comprises a gas inlet port for introduction of a gas to be plasmized provided near a discharge path for vacuum discharge of a processing chamber where the film formation is carried out (see, for example, claim 1 and FIG. 1). It is disclosed that this device can achieve a homogenous film thickness distribution in the in-plane direction by reducing pressure gradient in the processing chamber (see paragraph 0019).

Patent document 2 discloses a film formation device, which comprises a gas limiting means (or a gas controlling means) for limiting flow of a gas to be plasmized provided at a partition region between a processing chamber, where the film formation is carried out, and a discharge chamber (see claims 1, 2, 4 and 5). As a specific aspect, the gas limiting means including: a gas limiting plate disposed at the partition region between the processing chamber and the discharge chamber; and a shutter disposed at the discharge chamber is disclosed (see, for example, claims 7 and 8, and FIG. 1).

Patent document 2 teaches that the gas limiting means allows provision of a homogenous plasma density distribution in the processing chamber (see claims 1 and 4) and reduction of the pressure gradient of the gas in the processing chamber (see claims 2 and 5), and that these effects provide the homogenous film thickness distribution in the in-plane direction (see, for example, paragraph 0024).

Patent document 2 further teaches that a homogenous potential distribution around an object to be processed can be achieved by the gas limiting means with surrounding both the gas introduction side and the discharge side with ground surfaces (see, for example, claims 3 and 6), and this is also effective to achieve the homogenous film thickness distribution in the in-plane direction (see, for example, paragraph 0024).

Theoretically, the composition of a film formed through sputtering should be substantially the same as the composition of a target. However, if the constituent elements of the film include an element with high vapor pressure, the element tends to be subject to reverse sputtering on the surface of the formed film, and this may often make it difficult to provide the film with substantially the same composition as the composition of the target.

The reverse sputtering is a phenomenon in which, if there is a large difference in ease of sputtering (sputter rate) among the constituent elements, one of the constituent elements which is more susceptible to sputtering than the other elements deposited on the substrate is preferentially sputtered out of the surface of the film by the sputter particles, although the elements sputtered from the target have almost the same composition as the target.

For example, in PZT (lead zirconate titanate), which is a perovskite oxide with high ferroelectricity, Pb is more susceptible to the reverse sputtering than Ti and Zr, and thus the Pb concentration in the film tends to be lower than the Pb concentration in the target. Also, in a perovskite oxide containing Bi or Ba at the A-site, these elements have high vapor pressure and thus have the similar tendency.

In Zn-containing compounds, Zn has high vapor pressure and thus has the similar tendency. For example, in a zinc oxide transparent conductive film or transparent semiconductor film, such as InGaZnO₄(IGZO), which has excellent electric and optical characteristics comparable to indium tin oxide (ITO) and which is inexpensive and is an abundant resource, Zn is more subject to the reverse sputtering than the other constituent elements, and the Zn contents in the film composition tends to be lower than that in the target composition.

In order to obtain a desired composition for the systems as presented in the above examples, countermeasures, such as using a target which contains the element susceptible to the reverse sputtering with an increased concentration, have been taken.

The present inventors have formed a PZT film on a substrate with 6-inch diameter using a commercially available sputtering device, and have found that the Pb concentration of the film varies in the in-plane direction (see comparative examples 1 and 2, which will be described later). With a composition which is susceptible to the reverse sputtering, it is considered to be necessary to more strictly control film formation conditions to provide homogenous conditions in the in-plane direction.

Although patent documents 1 and 2 teach that a homogenous gas pressure or a homogenous plasma density distribution is provided in the processing chamber by controlling the gas flow, the level of homogeneity is not described and is unclear.

In the structure disclosed in patent document 1, the gas is introduced through a single port provided on a lateral side relative to the substrate, and is discharged to the same side. In the structure disclosed in patent document 2, the gas is introduced from a lateral side relative to the substrate, and is discharged to the other lateral side with limiting the discharge of the gas with the gas limiting means. Since the control of the gas flow is exerted only from the lateral side(s) relative to the substrate in both the structures, it can hardly be said that high level homogenization of the gas pressure distribution in the in-plane direction of the substrate within the processing chamber is achievable. In the structure disclosed in patent document 1, the gas inlet port is disposed near the discharge path, and therefore the gas introduced into the processing chamber is immediately discharged. Thus, it may be highly likely that a necessary amount of gas is not fed into the processing chamber.

Patent documents 1 and 2 pertain to film formation with sputtering in general, for which strict conditions, such as conditions required for a composition system susceptible to the reverse sputtering, are not required, and the homogenization level of the gas pressure and the plasma density distribution within the processing chamber is not high. Therefore, high level reduction of the variation of the composition in the in-plane direction cannot be achieved even when the structure disclosed in patent document 1 or 2 is applied to the composition system susceptible to the reverse sputtering.

The above-described problem is not limited to the case of sputtering, and the similar problem may occur in other film formation methods in which a substrate and a target are placed to face each other and a film containing the constituent elements of the target is formed on a substrate through vapor deposition using plasma. This problem is more apparent when the substrate size is larger, such as a substrate with 6-inch diameter.

### DISCLOSURE OF INVENTION

In view of the above-described circumstances, the present invention is directed to providing a film formation method and a film formation device which are preferably applicable to a composition system, etc., susceptible to reverse sputtering, and allow high-level homogenization of film properties, such as composition, in the in-plane direction regardless of the composition of formed film and the substrate size.

The present invention is further directed to providing a piezoelectric film which is formed with the above film formation method and has highly homogenized film properties, such as composition, in the in-plane direction.

The commercially-available sputtering device used by the present inventors has a vacuum vessel including an inner vessel and an outer vessel. The gas is introduced through a single gas nozzle into an air gap between the inner vessel and the outer vessel, and the gas filled in the air gap between the inner vessel and the outer vessel flows into the inner vessel. As just described, the conventional sputtering device includes an annular gas jetting member for jetting the gas into a vacuum vessel (in the above-described aspect, the inner vessel and the outer vessel comprise the annular gas jetting member, and the gas is jetted into the vacuum vessel through the air gap between the inner vessel and the outer vessel), and a single gas feeding member (the gas nozzle in the above-described aspect) connected to the gas jetting member for feeding the gas to the gas jetting member from the outside of the vacuum vessel.

The present inventors have found that the Pb concentration in the PZT film formed using the conventional sputtering device tends to be higher at a side closer to the gas feeding member and lower at a side farther from the gas feeding member. The present inventors have found that the conventional gas introduction structure does not provide homogenous jet of the gas from the annular gas jetting member into the vacuum vessel since the gas is introduced into the annular gas jetting member through a single port, and that the inhomogeneous gas pressure generates variation in plasma potential Vs (V) in the plasma space. It is considered that, at a side where the gas pressure is relatively high, the vacuum is relatively low and the plasma potential Vs (V) is relatively low, and thus tendency of the reverse sputtering of Pb is relatively low, resulting in the relatively high Pb concentration. The present inventors have found that the plasma potential Vs (V) in the plasma space can be homogenized by homogenizing the gas flow into the vacuum vessel, thereby achieving the invention.

The film formation method of the invention is a film formation method of forming, on a substrate, a film containing constituent elements of a target through a vapor deposition technique using plasma with placing the substrate and the target to face each other, the method including: carrying out the film formation with controlling variation of plasma potential Vs (V) in a plasma space in the in-plane direction of the substrate to be within plus or minus 10V at a distance of 2-3 cm from the surface of the target toward the substrate.

A position at a distance of 1.0-1.5 cm from the surface of the target toward the substrate is called a sheath. In the invention, the film formation is carried out with controlling the variation of the plasma potential Vs (V) to be within the above-described range at the distance of 2-3 cm from the surface of the target toward the substrate (which position is a little closer to the substrate from the sheath).

“The plasma potential Vs and the floating potential Vf” herein are measured through a single probe method using a Langmuir probe. Measurement of the floating potential Vf is conducted in a short time as possible, with placing the distal end of the probe in the vicinity of the substrate to avoid such a situation that the film being formed, or the like, adheres to the probe and introduces error. A potential difference Vs-Vf (V) between the plasma potential Vs and the floating potential Vf can be converted into an electron temperature (eV). The electron temperature of 1 eV is equivalent to 11600 K (K means absolute temperature).

In the film formation method of the invention, it is preferable that the film formation is carried out with controlling variation of gas pressure in the in-plane direction of the substrate to be within plus or minus 1.5% at the distance of 2-3 cm from the surface of the target toward the substrate.

The present inventors have found that the variation of the plasma potential Vs (V) can be controlled to be within the range defined in the invention by controlling the variation of the gas pressure to be within the above-described range.

The “variation of the plasma potential Vs or the gas pressure at the distance of 2-3 cm from the surface of the target toward the substrate” herein is defined by the variation within a region having the same area as the target with a point at the distance of 2-3 cm from the center of the target toward the substrate being a reference point.

As mentioned in the “Background Art” above, patent documents 1 and 2 teach to homogenize the gas pressure or the plasma density distribution within the processing chamber by controlling the gas flow. However, the devices disclosed in patent documents 1 and 2 cannot achieve high level homogenization of the gas pressure as is defined in the invention.

An example of the vapor deposition technique applicable to the invention is sputtering.

The invention is preferably applicable to a case where the film is a piezoelectric film.

The invention is preferably applicable to a case where the film is a piezoelectric film which contains, as a main component, one or two or more perovskite oxides represented by general formula (P) below:

ABO₃ (P),

wherein A represents an A-site element and includes at least one element selected from the group consisting of Pb, Ba, Sr, Bi, Li, Na, Ca, Cd, Mg, K, and lanthanide elements; B represents a B-site element and includes at least one element selected from the group consisting of Ti, Zr, V, Nb, Ta, Cr, Mo, W, Mn, Mg, Sc, Co, Cu, In, Sn, Ga, Zn, Cd, Fe, Ni, Hf and Al; and O represents oxygen, and wherein the molar ratio of the A-site element, the B site element and the oxygen element is 1:1:3 as a standard; however, the molar ratio may be varied from the standard molar ratio within a range where a perovskite structure is obtained.

The “main component” herein refers to a component whose content is at least 80 mol %.

The invention is preferably applicable to a case where the film contains one or two or more perovskite oxides represented by general formula (P), and the A-site element includes at least one metal element selected from the group consisting of Pb, Bi and Ba.

The invention is preferably applicable to a case where the film contains a Zn-containing compound.

The invention is preferably applicable to a case where the film contains a Zn-containing oxide represented by general formula (S) below:

InₓM_{y}Zn_{z}O_{(x+3y/2+3z/2)} (S),

wherein M represents at least one element selected from the group consisting of In, Fe, Ga and Al, and all of x, y and z are real numbers greater than 0.

The film formation device of the invention is a film formation device for forming, on a substrate, a film containing constituent elements of a target through vapor deposition using plasma, the film formation device including: a vacuum vessel containing therein a substrate holder and a target holder disposed to face to each other; plasma generating means for generating plasma within the vacuum vessel; and gas introducing means for introducing a gas to be plasmized into the vacuum vessel, wherein variation of plasma potential Vs (V) in a plasma space in an in-plane direction of the substrate is controlled to be within plus or minus 10V at a distance of 2-3 cm from the surface of the target toward the substrate.

In the film formation device of the invention, it is preferable that variation of gas pressure in the in-plane direction of the substrate is controlled to be within plus or minus 1.5% at the distance of 2-3 cm from the surface of the target toward the substrate.

In one aspect, the gas introducing means includes: an annular gas jetting member disposed between the substrate holder and the target holder in the vacuum vessel, the gas jetting member being adapted to receive the gas introduced thereto, the gas jetting member including a plurality of gas jet orifices for jetting the gas into the vacuum vessel; and a gas feeding member connected to the gas jetting member, the gas feeding member feeding the gas into the gas jetting member from the outside of the vacuum vessel.

In a preferred aspect of the gas introducing means, the gas feeding member is a plurality of gas feeding members connected to the gas jetting member at equal intervals, and the plurality of gas jet orifices are provided at equal intervals in the gas jetting member.

In another preferred aspect of the gas introducing means, the gas feeding member is a single gas feeding member connected to the gas jetting member, and the number of the gas jet orifices provided in the gas jetting member is relatively small at an area of the gas jetting member closer to the gas feeding member and the number of the gas jet orifices is relatively large at an area of the gas jetting member farther from the gas feeding member.

In the film formation device of the invention, it is preferable that the innermost wall surface of the vacuum vessel is electrically insulated or floating.

The piezoelectric film of the invention is formed with the above-described film formation method of the invention.

The piezoelectric device of the invention includes the above-described piezoelectric film of the invention, and an electrode for applying an electric field to the piezoelectric film.

The liquid discharge device of the invention includes the above-described piezo-electric device of the invention, and a liquid discharge member disposed adjacent to the piezoelectric device, the liquid discharge member including a liquid reservoir for storing a liquid, and a liquid discharge port for discharging the liquid from the liquid reservoir to the outside in response to application of the electric field to the piezo-electric film.

According to the present invention, a film formation method and a film formation device can be provided, which are preferably applicable to a composition system, etc., susceptible to reverse sputtering and which allow high level homogenization of film properties, such as composition, in the in-plane direction regardless of the composition of a formed film and the size of a substrate.

According to the invention, a piezoelectric film with highly homogenized film properties, such as composition, in the in-plane direction formed with the above-described film formation method can be provided.

### BRIEF DESCRIPTION OF DRAWINGS

FIG. 1A is a sectional view illustrating the entire structure of a film formation device according to one embodiment of the invention,

FIG. 1B is a plan view illustrating a gas introducing means, etc.,

FIG. 2A is a sectional view illustrating a modified example of the film formation device,

FIG. 2B is a plan view illustrating a modified example of a gas introducing means,

FIG. 3 is a diagram schematically illustrating how a film is formed,

FIG. 4 is an explanatory diagram illustrating how a plasma potential Vs and a floating potential Vf are measured,

FIG. 5 is a sectional view illustrating the structure of a piezoelectric device and an inkjet recording head (liquid discharge device according to one embodiment of the invention,

FIG. 6 is a diagram illustrating an example configuration of an inkjet recording device including the inkjet recording head of FIG. 5,

FIG. 7 is a partial plan view of the inkjet recording device of FIG. 6, and

FIG. 8 shows simulation data of comparative example 2.

### BEST MODE FOR CARRYING OUT THE INVENTION

(Film Formation Device and Film Formation Method Using the Same)

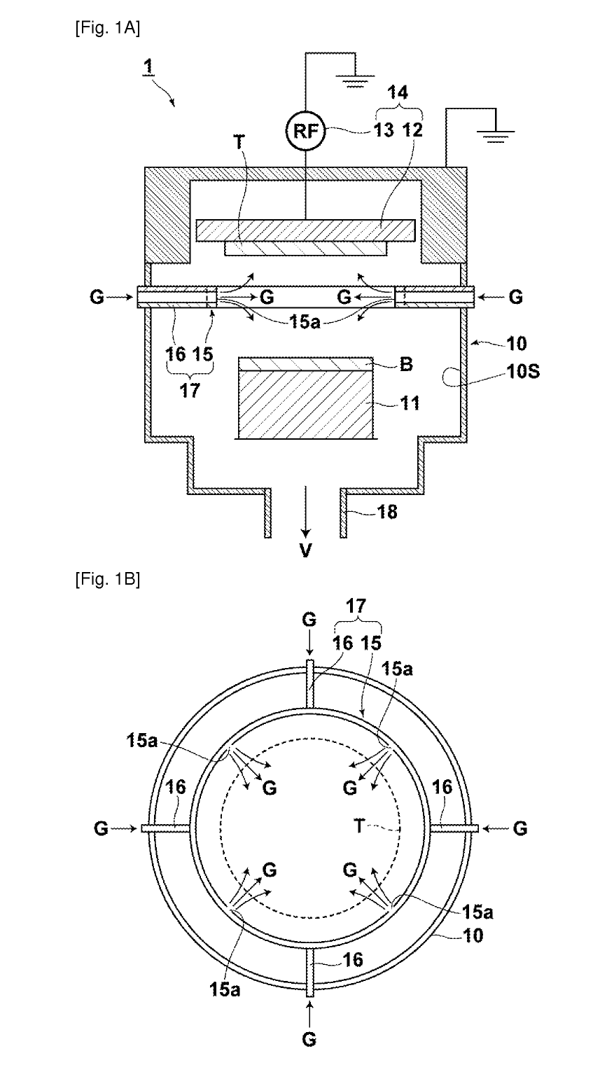

Now, a film formation device according to one embodiment of the present invention and a film formation method using the device will be described with reference to the drawings. FIG. 1A is a sectional view illustrating the entire structure of the device, and FIG. 1B is a plan view showing a gas introducing means 17, etc., viewed from the side of a substrate B.

The invention is applicable to film formation devices in which a substrate and a target are placed to face each other, and a film containing constituent elements of a target is formed on the substrate through vapor deposition using plasma.

Examples of the vapor deposition technique to which the invention is applicable include sputtering techniques, such as dipolar sputtering, tripolar sputtering, DC sputtering, radio frequency sputtering (RF sputtering), ECR sputtering, magnetron sputtering, facing target sputtering, pulse sputtering, and ion beam sputtering. Other examples of the vapor deposition technique, besides the sputtering technique, to which the invention is applicable include ion plating and plasma CVD. In this embodiment, the description is given in conjunction with radio frequency sputtering (RF sputtering), as an example.

A film formation device (radio frequency sputtering device) 1 shown in FIG. 1 generally includes a vacuum vessel 10, which includes therein a substrate holder 11, on which the substrate B can be loaded and the loaded substrate B can be heated to a pre-determined temperature; and a target holder 12, on which a target T can be loaded. In the device in this embodiment, the interior of the vacuum vessel 10 forms a film formation chamber.

In the vacuum vessel 10, the substrate holder 11 and the target holder 12 are spaced from each other to face to each other. The target holder 12 is connected to a radio frequency power supply (RF power supply) 13, which is disposed outside the vacuum vessel 10, so that the target holder 12 serves as a plasma electrode (cathode electrode) for generating plasma. In this embodiment, the radio frequency power supply 13 and the target holder 12 serving as the plasma electrode (cathode electrode) form a plasma generating means 14 for generating plasma in the vacuum vessel 10.

The substrate B is not particularly limited, and may be selected as appropriate according to the use from various substrates, such as Si substrates, oxide substrates, glass substrates, and various types of flexible substrates. The composition of the target T is selected according to the composition of the film to be formed.

The film formation device 1 includes a gas introducing means 17 for introducing a gas G to be plasmized into the vacuum vessel 10. In this embodiment, the gas introducing means 17 includes: an annular gas jetting member 15, which is disposed between the substrate holder 11 and the target holder 12 in the vacuum vessel 10, is able to receive the gas G introduced thereto, and has a plurality of gas jet orifices 15a for jetting the gas G into the vacuum vessel 10; and gas feeding members 16, which are, for example, gas nozzles or gas tubes connected to the gas jetting member 15 and feed the gas G into the gas jetting member 15 from the outside of the vacuum vessel 10. The gas G is not particularly limited, and may be Ar, Ar/O₂mixed gas, etc.

While conventional sputtering devices are provided with a single gas feeding member, the plurality of gas feeding members 16 are provided in this embodiment. In this embodiment, the gas feeding members 16 having the same inner diameter are connected to the gas jetting member 15 at equal intervals, and the plurality of gas jet orifices 15a having the same bore diameter are provided in the gas jetting member 15 at equal intervals. The numbers of the gas jet orifices 15a and the gas feeding members 16 are not particularly limited, and the numbers may or may not be the same. In the example shown in the drawing, four gas jet orifices 15a and four gas feeding members 16 are provided.

As shown in FIG. 1B, considering the homogeneity of the gas flow into the vacuum vessel 10, positions of the gas jet orifices 15a in the gas jetting member 15 and positions where the gas feeding members 16 are connected to the gas jetting member 15 are preferably offset from each other. With this structure, the gas G introduced from the gas feeding members 16 into the gas jetting member 15 is not immediately released through the gas jet orifices 15a, and is released through the gas jet orifices 15a after the gas G has circulated in the jetting member 15 to a certain extent.

A gas outlet tube 18 for discharging (V) the gas in the vacuum vessel 10 is connected to the vacuum vessel 10. The position where the gas outlet tube 18 is connected is not particularly limited, and the gas outlet tube 18 in this embodiment is connected to the bottom of the vacuum vessel 10.

With the structure of the gas introducing means 17 shown in FIGS. 1A and 1B, the gas G is homogenously introduced into the annular gas jetting member 15 at the plurality of points, and the gas G is jetted homogenously into the vacuum vessel 10 through the plurality of gas jet orifices 15a provided in the annular gas jetting member 15. The present inventors have found that, with this structure, variation of the gas pressure in the in-plane direction of the substrate B at a distance of 2-3 cm from the surface of the target T toward the substrate B can be controlled to be within plus or minus 1.5%.

The film formation pressure is not particularly limited; however, is preferably 10 Pa or less. If the film formation pressure is higher than 10 Pa, ratio of the particles sputtered out from the target T and reaching the substrate B may be reduced due to scattering, etc., depending on the types of the elements. If the film formation pressure is 10 Pa or less, the condition of the plasma space is between an intermediate flow, which is intermediate between the molecule flow and the viscous flow, and the molecule flow, and therefore possibility of the particles sputtered out from the target T to be scattered before they reach the substrate B is negligibly low regardless of the types of the elements.

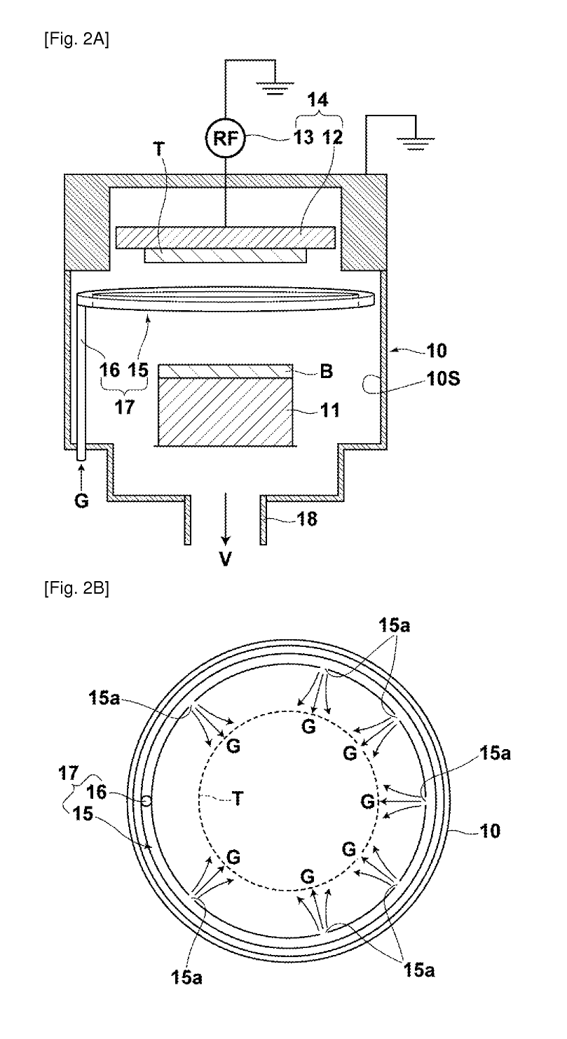

Alternatively, the gas introducing means 17 may have the structure shown in FIGS. 2A and 2B. FIG. 2A shows the gas introducing means 17 in perspective. In the aspect shown in FIGS. 2A and 2B, a single gas feeding member 16 is connected to the gas jetting member 15, where the number of the gas jet orifices 15a provided in the gas jetting member 15 is relatively small at an area closer to the gas feeding member 16 and the number of the gas jet orifices 15a is relatively large at an area farther from the gas feeding member 16.

In the structure having the single gas feeding member 16 connected to the gas jetting member 15, amount of the gas fed by the gas jetting member 15 is larger at the area closer to the gas feeding member 16. Therefore, the structure shown in FIGS. 2A and 2B allows the gas G to be homogenously jetted from the gas jetting member 15 into the vacuum vessel 10, and the same effect as that of the structure shown in FIGS. 1A and 1B can be provided.

In place of the structure shown in FIGS. 2A and 2B, the structure having the single gas feeding member 16 connected to the gas jetting member 15 may include the plurality of gas jet orifices 15a provided at equal intervals. In this structure, the gas jet orifices 15a closer to the gas feeding member 16 may have a relatively small bore diameter, and the gas jet orifices 15a farther from the gas feeding member 16 may have a relatively large bore diameter.

As schematically shown in FIG. 3, the gas G introduced into the vacuum vessel 10 is plasmized through electric discharge from the plasma electrode (in this embodiment, the target holder 12 serves as the plasma electrode), and positive ions Ip, such as Ar ions, generate. The generated positive ions Ip sputter the target T. Constituent elements Tp of the target T sputtered by the positive ions Ip are released from the target and deposited on the substrate B in the neutral or ionized state. In the drawing, the plasma space is denoted by the symbol “P”.

The potential in the plasma space P is a plasma potential Vs (V). Usually, the substrate B is an insulator and is electrically insulated from the ground. Thus, the substrate B is floating, and the potential of the substrate B is a floating potential Vf (V). It is considered that, during film formation, the constituent elements Tp of the target present between the target T and the substrate B collide against the substrate B with a kinetic energy corresponding to an accelerating voltage, which corresponds to a potential difference Vs-Vf between the plasma potential Vs in the plasma space P and the potential Vf at the substrate B.

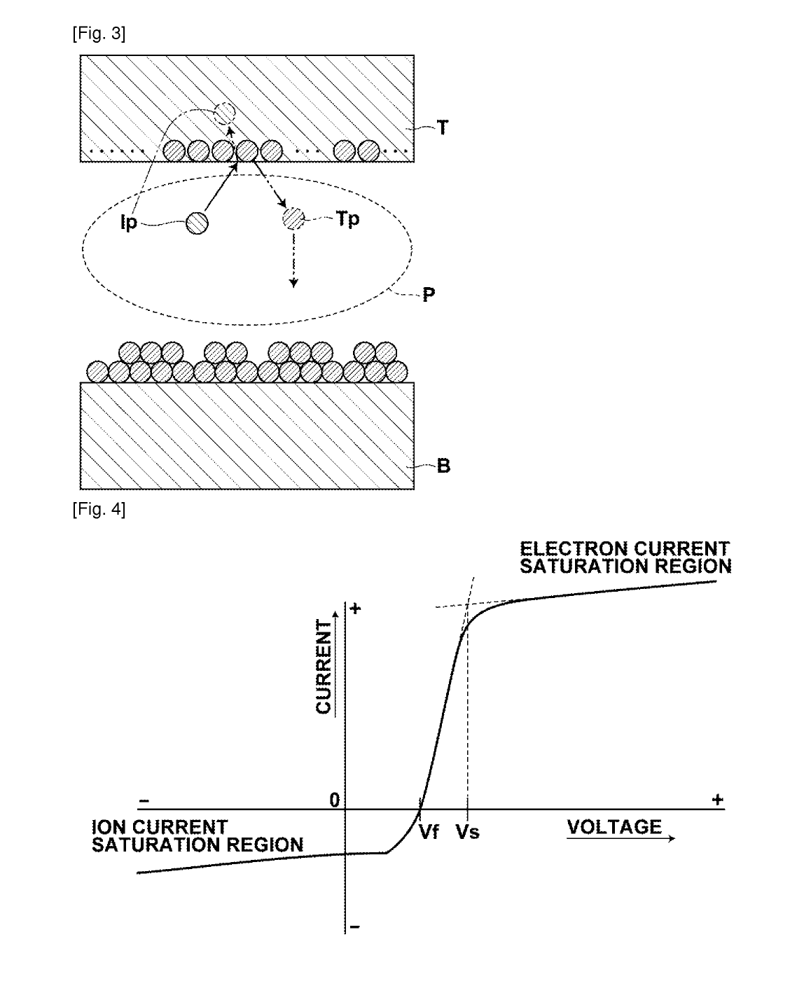

The plasma potential Vs and the substrate potential Vf can be measured using a Langmuir probe. Placing the distal end of the Langmuir probe in plasma P and varying a voltage applied to the probe, current-voltage characteristics as shown in FIG. 4, for example, is obtained (Mitsuharu Konuma, “Purazuma-to-Seimaku-no-Kiso (Fundamentals of Plasma and Film Formation)”, p. 90, published by Nikkan Kogyo Shimbun, Ltd.). In this graph, the probe potential corresponding to the current of 0 is the floating potential Vf. At this point, the amount of ion current and the amount of electron current flowing to the surface of the probe are equal to each other. The surface of an insulated metal or the surface of an insulated substrate has this potential. As the probe voltage is gradually increased from the floating potential, the ion current gradually decreases, and finally, only the electron current reaches the probe. The voltage at this boundary is the plasma potential Vs.

The present inventors have found that, with the structure of this embodiment, variation of the gas pressure in the in-plane direction of the substrate B at a distance of 2-3 cm from the surface of the target T toward the substrate B can be controlled to be within plus or minus 1.5%, and thus, variation of the plasma potential Vs (V) in the plasma space in the in-plane direction of the substrate B at the distance of 2-3 cm from the surface of the target T toward the substrate B can be controlled to be within plus or minus 10V.

That is, the film formation method of the invention is a film formation method in which a substrate and a target are placed to face each other, and a film containing constituent elements of a target is formed on a substrate through vapor deposition using plasma, the method being characterized by carrying out the film formation with controlling variation of plasma potential Vs (V) in a plasma space in the in-plane direction of the substrate to be within plus or minus 10V at a distance of 2-3 cm from the surface of the target toward the substrate.

In the film formation method of the invention, it is preferable that the film formation is carried out with controlling variation of gas pressure in the in-plane direction of the substrate to be within plus or minus 1.5% at the distance of 2-3 cm from the surface of the target toward the substrate.

The present inventors have found that, by controlling the variation of the gas pressure in the in-plane direction of the substrate B to be within plus or minus 1.5% at the distance of 2-3 cm from the surface of the target T toward the substrate B, and controlling the variation of the plasma potential Vs (V) in the in-plane direction of the substrate B to be within plus or minus 10V at the same position, film properties, such as composition, in the in-plane direction can be highly homogenized regardless of the composition of the formed film and the substrate size.

In the film formation device 1, it is preferable that an innermost wall surface 10S of the vacuum vessel 10 is electrically insulated or floating. For example, the inner surface of the vacuum vessel 10 may be covered with an insulating film to make the innermost wall surface 10S of the vacuum vessel 10 be electrically insulated or floating.

The present inventors have found that, if the innermost wall surface 10S of the vacuum vessel 10 is grounded, the plasma potential Vs (V) in the plasma space tends to fluctuate, and thus film properties, such as composition, of the formed film tends to vary. If the innermost wall surface 10S of the vacuum vessel 10 is electrically insulated or floating, the plasma potential Vs (V) in the plasma space is stabilized to provide the homogenous plasma potential Vs (V), and thus variation of film properties, such as composition, of the formed film is reduced.

The film formation device 1 of this embodiment and the film formation method using the device are applicable to formation of a film having any composition. The film formation device 1 of this embodiment and the film formation method using the device are preferably applicable to a composition system, etc., which is susceptible to the reverse sputtering, and even with such a composition system, film properties, such as composition, in the in-plane direction can be highly homogenized.

The susceptibility to sputtering is often represented by sputter rate, such that the higher the sputter rate, the higher the susceptibility. The “sputter rate” is defined by a ratio between the number of incoming ions and the number of sputtered atoms, and the unit is (atoms/ion).

It has been known that, among the constituent elements Pb, Zr and Ti of PZT, Pb has the highest sputter rate, i.e., is most susceptible to sputtering. For example, Table 8.1.7 shown in “Shinku Handobukku (Handbook of Vacuum Technology) ” (edited by ULVAK, Inc., published by Ohmsha, Ltd.) shows that the sputter rates under the condition of 300 eV Ar ion is: Pb=0.75, Zr=0.48 and Ti=0.65. This means that the susceptibility to sputtering of Pb is 1.5 times or more the susceptibility to sputtering of Zr.

The invention is preferably applicable to formation of a piezoelectric film.

The invention is preferably applicable to formation of a piezoelectric film containing, as a main component, one or two or more perovskite oxides represented by general formula (P) below:

ABO₃ (P),

wherein A represents an A-site element and includes at least one element selected from the group consisting of Pb, Ba, Sr, Bi, Li, Na, Ca, Cd, Mg, K, and lanthanide elements; B represents a B-site element and includes at least one element selected from the group consisting of Ti, Zr, V, Nb, Ta, Cr, Mo, W, Mn, Mg, Sc, Co, Cu, In, Sn, Ga, Zn, Cd, Fe, Ni, Hf and Al; and 0 represents oxygen. The molar ratio of the A-site element, the B site element and the oxygen element is 1:1:3 as a standard; however, the molar ratio may be varied from the standard molar ratio within a range where a perovskite structure is obtained.

Examples of the perovskite oxides represented by general formula (P) includes: lead-containing compounds, such as lead titanate, lead zirconate titanate (PZT), lead zirconate, lead lanthanum titanate, lead lanthanum zirconate titanate, lead magnesium niobate zirconium titanate, lead nickel niobate zirconium titanate and lead zinc niobate zirconium titanate, as well as mixed crystal systems thereof; and non-lead-containing compounds, such as barium titanate, strontium barium titanate, bismuth sodium titanate, bismuth potassium titanate, sodium niobate, potassium niobate and lithium niobate, as well as mixed crystal systems thereof.

In view of improvement of electrical characteristics, the perovskite oxide represented by general formula (P) preferably contains one or two or more metal ions, such as Mg, Ca, Sr, Ba, Bi, Nb, Ta, W, and Ln (=lanthanide elements: La, Ce, Pr, Nd, Sm, Eu, Gd, Tb, Dy, Ho, Er, Tm, Yb and Lu).

The invention is preferably applicable to formation of a film containing one or two or more perovskite oxides represented by general formula (P) and having the A-site element which is at least one metal element selected from the group consisting of Pb, Bi and Ba. Pb, Bi or Ba is an element having high vapor pressure and susceptible to the reverse sputtering.

Examples of the perovskite oxide represented by general formula (P) and containing

Pb include lead titanate, lead zirconate titanate (PZT), lead zirconate, lead lanthanum titanate, lead lanthanum zirconate titanate, lead magnesium niobate zirconium titanate, and lead nickel niobate zirconium titanate.

Examples of the perovskite oxide represented by general formula (P) and containing Bi or Ba include barium titanate, barium strontium titanate, barium titanate zirconate, bismuth sodium titanate, bismuth potassium titanate, bismuth ferrite, bismuth ferrite lanthanum, and bismuth ferrite barium.

The invention is preferably applicable to formation of a film containing a Zn-containing compound. Zn is also an element having high vapor pressure and susceptible to the reverse sputtering.

The invention is preferably applicable to formation of a film containing a Zn-containing oxide represented by general formula (S) below:

InₓM_{y}Zn_{z}O_{(x+3y/2+3z/2)} (S),

where M represents at least one element selected from the group consisting of In, Fe, Ga and Al. All of x, y and z are real numbers greater than 0.

Examples of the Zn-containing oxide represented by general formula (S) include

InGaZnO₄ (IGZO) and ZnIn₂O₄, which are used as a transparent conductive film or a transparent semiconductor film in various applications.

As described above, according to this embodiment, the film formation device 1 and the film formation method which are preferably applicable to a composition system, etc., susceptible to the reverse sputtering, and allow high level homogenization of film properties, such as composition, in the in-plane direction regardless of the composition of the formed film and the substrate size, can be provided.

The present inventors have confirmed that the highly homogenized film properties, such as composition, in the in-plane direction can be obtained in cases where a film of a composition system susceptible to the reverse sputtering is formed on a substrate having a diameter of three inches or more, or even six inches or more (see examples 1 and 2, which will be described later).

(Piezoelectric Device and Inkjet Recording Head)

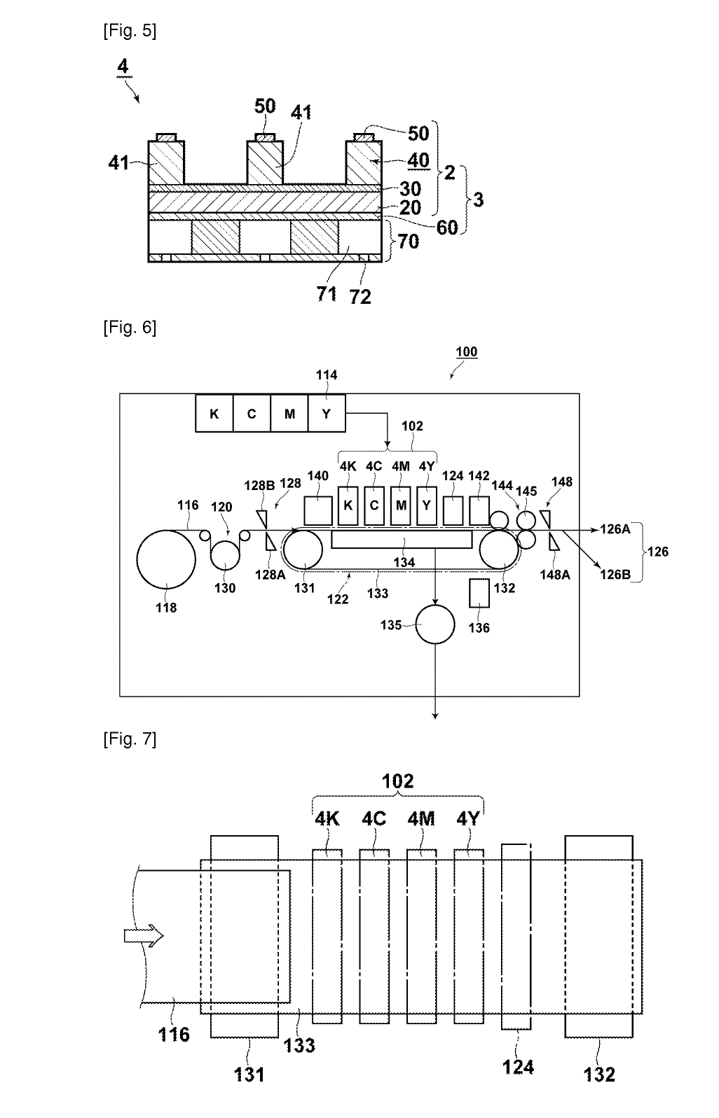

Now, structures of a piezoelectric device according to one embodiment of the invention and an inkjet recording head (liquid discharge device) including the piezo-electric device are described with reference to FIG. 5. FIG. 5 is a sectional view of a main portion of the inkjet recording head (a sectional view taken along the thickness direction of the piezoelectric device). For ease of visual understanding, the components shown in the drawing are not to scale.

A piezoelectric device 2 of this embodiment includes a substrate 20, and a lower electrode 30, a piezoelectric film 40 and upper electrodes 50 which are sequentially formed on the substrate 20. An electric field in the thickness direction is applied to the piezoelectric film 40 via the lower electrode 30 and the upper electrodes 50.

The lower electrode 30 is formed over substantially the entire surface of the substrate 20. The piezoelectric film 40, which is formed by line-shaped protrusions 41 arranged in stripes pattern extending in a direction perpendicular to the plane of the drawing, is formed on the lower electrode 30, and the upper electrodes 50 are formed on the individual protrusions 41.

The pattern of the piezoelectric film 40 is not limited to one shown in the drawing, and may be designed as appropriate. Alternatively, the piezoelectric film 40 may be a continuous film. However, when the piezoelectric film 40 is not a continuous film and has the pattern including the plurality of separate protrusions 41, the individual protrusions 41 can smoothly expand or contract, thereby preferably providing larger displacement.

The substrate 20 is not particularly limited, and may be any of various substrates, such as silicon, glass, stainless steel (SUS), yttrium stabilized zirconia (YSZ), alumina, sapphire and silicon carbide. The substrate 20 may be a multilayer substrate, such as a SOI substrate including a SiO₂ oxide film formed on the surface of a silicon substrate.

The composition of the lower electrode 30 is not particularly limited, and examples thereof may include a metal or a metal oxide, such as Au, Pt, Ir, IrO₂, RuO₂, LaNiO₃, and SrRuO₃, as well as combinations thereof. The composition of the upper electrode 50 is not particularly limited, and examples thereof may include the example materials described for the lower electrode 30, electrode materials commonly used in semi-conductor processes, such as Al, Ta, Cr and Cu, and combinations thereof. The thicknesses of the lower electrode 30 and the upper electrode 50 are not particularly limited; however, the thicknesses in the range from 50 to 500 nm are preferred.

The piezoelectric film 40 is formed with the film formation method using the above-described film formation device 1. The piezoelectric film 40 preferably contains, as a main component, one or two or more perovskite oxides represented by general formula (P) described above. It is more preferable that the piezoelectric film 40 contains one or two or more perovskite oxides represented by general formula (P) and has the A-site element which is at least one metal element selected from the group consisting of Pb, Bi and Ba. The film thickness of the piezoelectric film 40 is not particularly limited; however, it is usually 1 micro meter or more (for example, 1-5 micro meters).

A piezoelectric actuator 3 includes a vibrating plate 60, which vibrates along with expansion or contraction of the piezoelectric film 40, attached on the back side of the substrate 20 of the piezoelectric device 2. The piezoelectric actuator 3 also includes a controlling means (not shown), such as a driving circuit, for controlling drive of the piezoelectric device 2.

The inkjet recording head (liquid discharge device) 4 is generally includes, at the back side of the piezoelectric actuator 3, an ink nozzle (liquid storing and discharging member) 70 including an ink chamber (liquid reservoir) 71 for storing ink and an ink discharge port (liquid discharge port) 72 through which the ink is discharged from the ink chamber 71 to the outside. In the inkjet recording head 4, the piezoelectric device 2 expands or contracts when the intensity of the electric field applied to the piezoelectric device 2 is increased or decreased, thereby controlling discharge of the ink from the ink chamber 71 and the amount of the discharged ink.

In stead of providing the vibrating plate 60 and the ink nozzle 70, which are members separate from the substrate 20, parts of the substrate 20 may be machined to form the vibrating plate 60 and the ink nozzle 70. For example, if the substrate 20 is a multilayer substrate, such as a SOI substrate, the substrate 20 may be etched at the back side thereof to form the ink chamber 61, and then the substrate may be machined to form the vibrating plate 60 and the ink nozzle 70.

The structures of the piezoelectric device 2 and the inkjet recording head 4 of this embodiment are as described above. According to this embodiment, the piezoelectric film 40 which is formed with the above-described film formation method and has highly homogenized film properties, such as composition, in the in-plane direction, and the piezoelectric device 2 including the piezoelectric film 40 can be provided.

(Inkjet Recording Device)

Now, an example configuration of an inkjet recording device including the inkjet recording head 4 of the above-described embodiment is described with reference to FIGS. 6 and 7. FIG. 6 shows the entire device configuration, and FIG. 7 is a partial plan view.

An inkjet recording device 100 shown in the drawing generally includes: a printing section 102 having a plurality of inkjet recording heads (hereinafter simply referred to as “heads”) 4K, 4C, 4M and 4Y provided respectively for ink colors; an ink storing and charging section 114 for storing inks to be fed to the heads 4K, 4C, 4M and 4Y; a paper feeding section 118 for feeding recording paper 116; a decurling section 120 for decurling the recording paper 116; a suction belt conveyer section 122 disposed to face to the nozzle surface (ink discharge surface) of the printing section 102, for conveying the recording paper 116 with keeping the flatness of the recording paper 116; a print detection section 124 for reading the result of printing at the printing section 102; and a paper discharge section 126 for discharging the printed recording paper (a print) to the outside.

Each of the heads 4K, 4C, 4M and 4Y forming the printing section 102 corresponds to the inkjet recording head 4 in the above-described embodiment.

At the decurling section 120, the recording paper 116 is decurled with a heating drum 130 heating the recording paper 116 in a direction opposite to the direction of the curl.

In the device using the roll paper, a cutter 128 is provided downstream the decurling section 120, as shown in FIG. 6, so that the roll paper is cut by the cutter into a sheet of a desired size. The cutter 128 is formed by a fixed blade 128A, which has a length equal to or larger than the width of the conveyance path for the recording paper 116, and a round blade 128B, which moves along the fixed blade 128A. The fixed blade 128A is disposed on the back surface side of the print, and the round blade 128B is disposed on the print surface side via the conveyance path. In a case where the device uses cut sheets, the cutter 128 is not necessary.

The decurled and cut recording paper sheet 116 is sent to the suction belt conveyer section 122. The suction belt conveyer section 122 includes an endless belt 133 wrapped around rollers 131 and 132, and is formed such that at least an area of the belt facing the nozzle surface of the printing section 102 and a sensor surface of the print detection section 124 forms a horizontal (flat) surface.

The belt 133 has a width that is larger than the width of the recording paper sheet 116, and a number of suction holes (not shown) are formed in the belt surface. A suction chamber 134 is provided inside the belt 133 wrapped around the rollers 131 and 132 at a position where the suction chamber 134 faces the nozzle surface of the printing section 102 and the sensor surface of the print detection section 124. A suction force generated by a fan 135 provides the suction chamber 134 with a negative pressure, thereby holding the recording paper sheet 116 on the belt 133 with suction.

As a motive force from a motor (not shown) is transmitted to at least one of the rollers 131 and 132, around which the belt 133 is wrapped, the belt 133 is driven in the clockwise direction in FIG. 6, and the recording paper 116 held on the belt 133 is conveyed from the left to the right in FIG. 6.

In a case where margin-less printing, or the like, is carried out, the inks adhere on the belt 133. Therefore, a belt cleaning section 136 is provided at a predetermined position (any appropriate position other than the print region) outside the belt 133.

A heating fan 140 is provided upstream the printing section 102 on the paper sheet conveyance path formed by the suction belt conveyer section 122. The heating fan 140 blows heating air toward the recording paper sheet 116 to heat the recording paper sheet 116 before printing. Heating the recording paper sheet 116 immediately before printing promotes drying of the deposited ink.

The printing section 102 is a so-called full-line head, in which line heads, each having a length corresponding to the maximum paper width, are arranged in a direction (main scanning direction) perpendicular to the paper feed direction (see FIG. 7). Each recording head 4K, 4C, 4M, 4Y is formed by a line head, which has a plurality of ink discharge orifices (nozzles) provided across a length that is larger than at least one side of the recording paper sheet 116 of the maximum size intended to be printed by the inkjet recording device 100.

The heads 4K, 4C, 4M and 4Y corresponding to the respective color inks of black (K), cyan (C), magenta (M) and yellow (Y) are disposed in this order from the upstream along the feed direction of the recording paper sheet 116. By discharging the color inks from the heads 4K, 4C, 4M and 4Y while the recording paper sheet 116 is conveyed, a color image is recorded on the recording paper sheet 116.

The print detection section 124 is formed by a line sensor, or the like, which images the result of ink droplets deposited by the printing section 102, and the image of the deposited ink droplets read by the line sensor is used to detect discharge defects, such as clogging of the nozzles.

A drying section 142 formed, for example, by a heating fan for drying the printed image surface is disposed downstream the print detection section 124. Blowing hot air is preferable since contact with the printed surface should preferably be avoided until the printed inks dry.

A heating and pressurizing section 144 for controlling the gloss of the image surface is disposed downstream the drying section 142. The heating and pressurizing section 144 presses the image surface with a pressure roller 145 having a predetermined textured pattern on the surface thereof while heating the image surface, thereby transferring the textured pattern onto the image surface.

The thus obtained print is discharged at the paper discharge section 126. It is preferable that prints of intended images (prints on which intended images are printed) and test prints are separately discharged. The inkjet recording device 100 includes a sorting means (not shown) for sorting the prints of intended images and the test prints and switching the discharge paths to selectively send them to a discharge section 126A or 126B.

In a case where an intended image and a test print are printed at the same time on a large-sized paper sheet, a cutter 148 may be provided to cut off the test print area.

The configuration of the inkjet recording device 100 is as described above.

(Modification)

The invention is not limited to the above-described embodiments, and may be modified as appropriate without departing from the spirit and scope of the invention.

### EXAMPLES

Now, examples according to the invention and comparative examples are described.

### Example 1

A 20-nanometer thick Ti film and a 150-nanometer thick Jr lower electrode were sequentially formed on a 3-inch diameter SOI substrate through sputtering under the condition of substrate temperature of 350 degrees centigrade. Then, a 4-micrometer thick PZT piezoelectric film was formed on the resulting substrate through RF sputtering using the film formation device shown in FIGS. 1A and 1B. The inner surface of the vacuum vessel 10 was covered with an insulating film, and the innermost wall surface 10S of the vacuum vessel 10 was electrically insulated.

As shown in FIGS. 1A and 1B, the film formation device used in this example included the plurality of gas feeding members 16 having the same inner diameter which were connected to the gas jetting member 15 at equal intervals, and the plurality of gas jet orifices 15a having the same bore diameter which were provided in the gas jetting member 15 at equal intervals. The film formation device used in this example included four gas jet orifices 15a and four gas feeding members 16. The film formation gas used was Ar/O₂ mixed gas (=30 sccm/0.8 sccm). The film formation pressure in the film formation chamber was adjusted to 0.5 Pa. The gas pressure distribution was calculated in simulation, and the variation of the gas pressure in the in-plane direction of the substrate at the distance of 2-3 cm from the surface of the target toward the substrate was found to be within plus or minus 1.0%.

Other film formation conditions were as follows:

target: Pb₁₃(Zr_{0.52}Ti_{0.48})O₃

(150 mm diameter);

substrate temperature: 475 degrees centigrade; and

RF power: 500 W.

The plasma potential Vs (V) in the plasma space under the film formation conditions was measured. The measurement of the plasma potential Vs (V) was carried out at a plurality of points in the in-plane direction of the substrate at a distance of 2 cm from the surface of the target toward the substrate. The results are shown below. The variation of the plasma potential Vs (V) at the distance of 2 cm from the surface of the target toward the substrate was 35 plus or minus 2 (V), which was nearly homogenous.

At the center: Vs=35 (V),

at points at plus

or minus 4 cm from the center: Vs=36 (V), and

at points at plus

or minus 7 cm from the center: Vs=37 (V).

XRD analysis was carried out on the resulting PZT film, and the PZT film was found to be a (100)-oriented film having a perovskite structure. The PZT film was divided into a number of regions in the in-plane direction and XRD analysis was carried out for each region, and it was found that a good quality film with good crystalline orientation was formed across the in-plane direction.

The resulting PZT film was divided into nine regions in the in-plane direction, except a marginal region of 5 mm from the edge, and XRF composition analysis was carried out for each region. The variation of the molar ratio of Pb/(Zr+Ti) was found to be 1.07 plus or minus 0.03, which was nearly homogenous.

The substrate was replaced with a 6-inch diameter SOI substrate, and film formation was carried out in the similar manner as in example 1. As a result, a good quality film with good crystalline orientation and small variation of composition in the in-plane direction was formed across the in-plane direction, similarly to example 1.

### Example 2

A 20-nanometer thick Ti film and a 150-nanometer thick Ir lower electrode were sequentially formed on a 3-inch diameter SOI substrate in the similar manner as in example 1. Then, a PZT piezoelectric film was formed under the same conditions as in example 1, except that the film formation device shown in FIGS. 2A and 2B was used.

As shown in FIGS. 2A and 2B, the film formation device used in this example included the single gas feeding member 16 which was connected to the gas jetting member 15, where the number of the gas jet orifices 15a provided in the gas jetting member 15 was relatively small at the area closer to the gas feeding member 16 and the number of the gas jet orifices 15a was relatively large at the area farther from the gas feeding member 16.

As shown in FIGS. 2A and 2B, the film formation device used in this example included two gas jet orifices 15a provided at the area closer to the gas feeding member 16 and five gas jet orifices 15a provided at the area farther from the gas feeding member 16. The film formation gas used was Ar/O₂ mixed gas (=30 sccm/0.8 sccm). The film formation pressure in the film formation chamber was adjusted to 0.5 Pa. The gas pressure distribution was calculated in simulation, and the variation of the gas pressure in the in-plane direction of the substrate at the distance of 2-3 cm from the surface of the target toward the substrate was found to be within plus or minus 1.0%.

The plasma potential Vs (V) in the plasma space under the film formation conditions was measured. The measurement of the plasma potential Vs (V) was carried out at a plurality of points in the in-plane direction of the substrate at a distance of 2 cm from the surface of the target toward the substrate. The results are shown below. The variation of the plasma potential Vs (V) at the distance of 2 cm from the surface of the target toward the substrate was 35 plus or minus 3 (V), which was nearly homogenous.

At the center: Vs=35 (V),

at points at plus

or minus 4 cm from the center: Vs=36 (V), and

at points at plus

or minus 7 cm from the center: Vs=38 (V).

XRD analysis was carried out on the resulting PZT film, and the PZT film was found to be a (100)-oriented film having a perovskite structure. The PZT film was divided into a number of regions in the in-plane direction and XRD analysis was carried out for each region, and it was found that a good quality film with good crystalline orientation was formed across the in-plane direction.

The resulting PZT film was divided into nine regions in the in-plane direction, except a marginal region of 5 mm from the edge, and XRF composition analysis was carried out for each region. The variation of the molar ratio of Pb/(Zr+Ti) was found to be 1.07 plus or minus 0.03, which was nearly homogenous.

The substrate was replaced with a 6-inch diameter SOI substrate, and film formation was carried out in the similar manner as in example 2. As a result, a good quality film with good crystalline orientation and small variation of composition in the in-plane direction was formed across the in-plane direction, similarly to example 1.

Comparative Example 1

A 20-nanometer thick Ti film and a 150-nanometer thick Jr lower electrode were sequentially formed on a 3-inch diameter SOI substrate in the similar manner as in example 1. Then, a PZT piezoelectric film was formed under the same conditions as in example 1, except that a film formation device including a single gas feeding member 16 connected to the gas jetting member 15 and four gas jet orifices 15a provided in the gas jetting member 15 at equal intervals was used.

The gas pressure distribution was calculated in simulation, and the variation of the gas pressure in the in-plane direction of the substrate at the distance of 2-3 cm from the surface of the target toward the substrate was found to be plus or minus 2.0%. The plasma potential Vs (V) in the plasma space under the film formation conditions was measured. The measurement of the plasma potential Vs (V) was carried out at a plurality of points in the in-plane direction of the substrate at a distance of 2 cm from the surface of the target toward the substrate. The results are shown below. The variation of the plasma potential Vs (V) at the distance of 2 cm from the surface of the target toward the substrate was 30 plus or minus 12 (V), which was a large variation.

At the center: Vs=30 (V),

at points at 4 cm from the center toward the gas feeding member 16: Vs=26 (V), and

at points at 7 cm from the center in a direction away from the gas feeding member 16: Vs =42 (V).

The resulting PZT film was divided into nine regions in the in-plane direction, except a marginal region of 5 mm from the edge, and XRF composition analysis was carried out for each region. The molar ratio of Pb/(Zr+Ti) was 1.14 at the region nearest to the gas feeding member 16, and was 1.07 at the region farthest from the gas feeding member 16. Thus, large variation was observed in the molar ratio of Pb/(Zr+Ti).

Comparative Example 2

A 20-nanometer thick Ti film and a 150-nanometer thick Jr lower electrode were sequentially formed on a 3-inch diameter SOI substrate in the similar manner as in example 1. Then, a PZT piezoelectric film was formed under the same conditions as in example 2, except that a film formation device including a single gas feeding member 16 connected to the gas jetting member 15 and eight gas jet orifices 15a provided in the gas jetting member 15 at equal intervals was used.

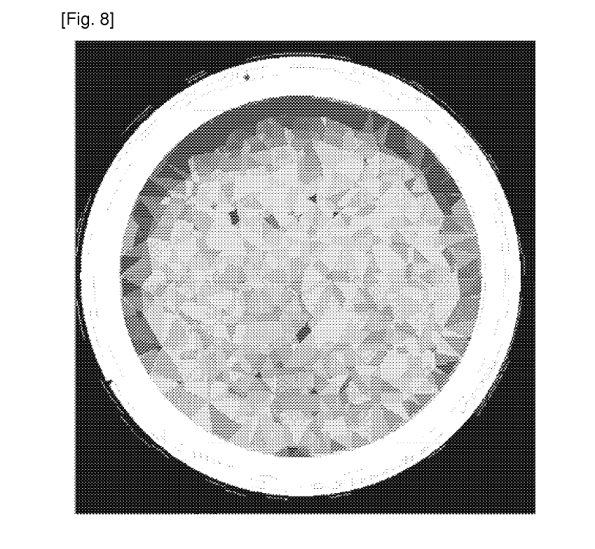

The gas pressure distribution was calculated in simulation, and the variation of the gas pressure in the in-plane direction of the substrate at the distance of 2-3 cm from the surface of the target toward the substrate was plus or minus 2.0%. The simulation data is shown in FIG. 8. In FIG. 8, the blacker areas indicate higher pressures and the whiter areas indicate lower pressures, where differences of the tone indicate differences of the pressure.

The plasma potential Vs (V) in the plasma space under the film formation conditions was measured. The measurement of the plasma potential Vs (V) was carried out at a plurality of points in the in-plane direction of the substrate at a distance of 2 cm from the surface of the target toward the substrate. The results are shown below. The variation of the plasma potential Vs (V) at the distance of 2 cm from the surface of the target toward the substrate was 32 plus or minus 12 (V), which was a large variation.

At the center: Vs=32 (V),

at points at 4 cm from the center toward the gas feeding member 16: Vs=28 (V), and

at points at 7 cm from the center in a direction away from the gas feeding member 16: Vs=44 (V).

The resulting PZT film was divided into nine regions in the in-plane direction, except a marginal region of 5 mm from the edge, and XRF composition analysis was carried out for each region. The molar ratio of Pb/(Zr+Ti) was 1.15 at the region nearest to the gas feeding member 16, and was 1.06 at the region farthest from the gas feeding member 16. Thus, large variation was observed in the molar ratio of Pb/(Zr+Ti).

Comparative Example 3

A 20-nanometer thick Ti film and a 150-nanometer thick Ir lower electrode were sequentially formed on a 3-inch diameter SOI substrate in the similar manner as in example 1. Then, a PZT piezoelectric film was formed under the same conditions as in example 1, except that a film formation device in which the inner surface of the vacuum vessel was provided with a ground potential was used.

The plasma potential Vs (V) in the plasma space under the film formation conditions was measured. The measurement of the plasma potential Vs (V) was carried out at a plurality of points in the in-plane direction of the substrate at a distance of 2 cm from the surface of the target toward the substrate. The results are shown below. The variation of the plasma potential Vs (V) at the distance of 2 cm from the surface of the target toward the substrate was 36 plus or minus 12 (V), which was a large variation.

At the center: Vs=36 (V),

at points at plus or minus 10 cm from the center: Vs=42 (V),

at points at plus or minus 14 cm from the center: Vs=48 (V).

XRD analysis was carried out on the resulting PZT film, and the PZT film was found to be a (100)-oriented film having a perovskite structure. The PZT film was divided into a number of regions in the in-plane direction, and XRD analysis was carried out for each region. As a result, the edge portion (a marginal region of 5 mm from the edge) contained a pyrochlore phase and thus had poor crystalline properties.

The resulting PZT film was divided into nine regions in the in-plane direction, except the marginal region of 5 mm from the edge, and XRF composition analysis was carried out for each region. As a result, the molar ratio of Pb/(Zr+Ti) was 1.05 plus or minus 0.1, and thus the composition homogeneity was poorer than that of example 1.

### INDUSTRIAL APPLICABILITY

The present invention is applicable to film formation through vapor deposition using plasma. The invention is applicable, for example, to formation of a piezoelectric film that is used in piezoelectric actuators provided in inkjet recording heads, magnetic read/write heads, MEMS (Micro Electro-Mechanical Systems) devices, micropumps, ultrasound probes, ultrasound motors, etc., and ferroelectric devices, such as ferro-electric memory, or formation of conductor films or semiconductor films containing a Zn-containing compound.

1.-17. (canceled)

18. A film formation method of forming, on a substrate, a film containing constituent elements of a target through a vapor deposition technique using plasma with placing the substrate and the target to face each other, the method comprising:
carrying out the film formation with controlling variation of plasma potential Vs (V) in a plasma space in an in-plane direction of the substrate to be within ±10V at a distance of 2-3 cm from a surface of the target toward the substrate.

19. The film formation method as claimed in claim 18, wherein the film formation is carried out with controlling variation of gas pressure in the in-plane direction of the substrate to be within ±1.5% at the distance of 2-3 cm from the surface of the target toward the substrate.

20. The film formation method as claimed in claim 18, wherein the vapor deposition technique comprises sputtering.

21. The film formation method as claimed in claim 18, wherein the film comprises a piezoelectric film.

22. The film formation method as claimed in claim 21, wherein the piezoelectric film comprises, as a main component, one or two or more perovskite oxides represented by general formula (P):
ABO₃ (P),
wherein A represents an A-site element and comprises at least one element selected from the group consisting of Pb, Ba, Sr, Bi, Li, Na, Ca, Cd, Mg, K, and lanthanide elements; B represents a B-site element and comprises at least one element selected from the group consisting of Ti, Zr, V, Nb, Ta, Cr, Mo, W, Mn, Mg, Sc, Co, Cu, In, Sn, Ga, Zn, Cd, Fe, Ni, Hf and Al; and O represents oxygen.

23. The film formation method as claimed in claim 22, wherein the A-site element in the piezoelectric film comprises at least one metal element selected from the group consisting of Pb, Bi and Ba.

24. The film formation method as claimed in claim 18, wherein the film comprises a Zn-containing compound.

25. The film formation method as claimed in claim 24, wherein the film comprises a Zn-containing oxide represented by general formula (S):
InₓM_{y}Zn_{z}O_{(x+3y/2+3z/2)} (S),
wherein M represents at least one element selected from the group consisting of In, Fe, Ga and Al, and all of x, y and z are real numbers greater than 0.

26. A film formation apparatus for forming, on a substrate, a film containing constituent elements of a target through vapor deposition using plasma, the film formation apparatus comprising:
a vacuum vessel comprising therein a substrate holder and a target holder disposed to face to each other;
plasma generating means for generating plasma within the vacuum vessel; and
gas introducing means for introducing a gas to be plasmized into the vacuum vessel,
wherein variation of plasma potential Vs (V) in a plasma space in an in-plane direction of the substrate is controlled to be within ±10V at a distance of 2-3 cm from the surface of the target toward the substrate.

27. The film formation apparatus as claimed in claim 26, wherein variation of gas pressure in the in-plane direction of the substrate is controlled to be within ±1.5% at the distance of 2-3 cm from the surface of the target toward the substrate.

28. The film formation apparatus as claimed in claim 26, wherein the gas introducing means comprises:
an annular gas jetting member disposed between the substrate holder and the target holder in the vacuum vessel, the gas jetting member being adapted to receive the gas introduced thereto, the gas jetting member comprising a plurality of gas jet orifices for jetting the gas into the vacuum vessel; and
a gas feeding member connected to the gas jetting member, the gas feeding member feeding the gas into the gas jetting member from the outside of the vacuum vessel.

29. The film formation apparatus as claimed in claim 28, wherein
the gas feeding member comprises a plurality of gas feeding members connected to the gas jetting member at equal intervals, and
the plurality of gas jet orifices are provided at equal intervals in the gas jetting member.

30. The film formation apparatus as claimed in claim 28, wherein
the gas feeding member comprises a single gas feeding member connected to the gas jetting member, and
the number of the gas jet orifices provided in the gas jetting member is relatively small at an area of the gas jetting member closer to the gas feeding member and the number of the gas jet orifices is relatively large at an area of the gas jetting member farther from the gas feeding member.

31. The film formation apparatus as claimed in claim 26, wherein an innermost wall surface of the vacuum vessel is electrically insulated or floating.

32. A piezoelectric film formed with the film formation method as claimed in claim 18.

33. A piezoelectric device comprising:
the piezoelectric film as claimed in claim 32; and
an electrode for applying an electric field to the piezoelectric film.

34. A liquid discharge device comprising:
the piezoelectric device as claimed in claim 33; and
a liquid discharge member disposed adjacent to the piezoelectric device, the liquid discharge member comprising a liquid reservoir for storing a liquid, and a liquid discharge port for discharging the liquid from the liquid reservoir to the outside in response to application of the electric field to the piezoelectric film.
